(19) United States
(12) Patent Application Publication
(10) Pub. No.: US 2023/0033309 A1
(43) Pub. Date: Feb. 2, 2023

(54) SEMICONDUCTOR LASER DEVICE

(71) Applicant: Panasonic Holdings Corporation, Osaka (JP)

(72) Inventors: SHINICHI TAKIGAWA, Osaka (JP); TSUYOSHI TANAKA, Osaka (JP)

(21) Appl. No.: 17/758,704

(22) PCT Filed: Jan. 18, 2021
(86) PCT No.: PCT/JP2021/001385

§ 371 Date: Jul. 13, 2022

(30) Foreign Application Priority Data
Feb. 21, 2020 (JP) 2020-028758

(51) Int. Cl. H01S 5/024; H01S 5/02253; H01S 5/02257

(52) U.S. Cl. CPC H01S 5/02423; H01S 5/02253; H01S 5/02257

(57) ABSTRACT

Provided is a semiconductor laser device enabling efficient emission of a laser beam without damaging a light emitting surface of a light emitting element. Semiconductor laser device includes light emitting element, optical element, first heat radiation part, and second heat radiation part. Laser beam emitted from light emitting element enters optical element. First heat radiation part is connected to light emitting element. Second heat radiation part is connected to light emitting element. First heat radiation part includes first recess. Second heat radiation part includes second recess. One end of optical element is fitted into first recess, and the other end of optical element is fitted into second recess.

### TECHNICAL FIELD

The present disclosure relates to a semiconductor laser device that emits laser beam.

### BACKGROUND ART

In recent years, various products have been processed using laser beam emitted from semiconductor laser devices. Laser processing has attracted attention as a means capable of performing welding, cutting, modifying, and the like for a material to be processed such as metal, resin, and carbon fiber with good controllability and cleanliness. Laser processing enables spot welding smaller than welding by arc discharge, for example. In addition, the laser processing enables generation of chips to be more suppressed as compared with cutting using a mold. Therefore, it is possible to achieve higher-quality processing as compared with these conventional processing means.

As laser beam for laser processing, there is a direct diode laser (DDL) method that directly uses a semiconductor laser beam. The DDL method has two characteristics that it is highly efficient because a laser beam is not converted and that processing is possible with a laser beam from ultraviolet to infrared by using a semiconductor laser element. In recent years, DDL having a light emission wavelength in a 400 nm band and using, in particular, a nitride semiconductor (GaN, InGaN, AlGaN, etc.) has attracted attention in that copper can be processed with high efficiency.

In general, an increase in output of a semiconductor laser can be achieved by increasing electric power that can be applied to an emitter that is a light emitting part by increasing a width of the emitter. However, light emission efficiency of a semiconductor laser is approximately 30% to 50%. Therefore, electric power that does not contribute to light emission becomes heat to increase temperature of the emitter. This temperature rise causes output heat saturation in the semiconductor laser, which is not preferable. Therefore, it is known to use an array structure (also referred to as a multi-emitter) in which a large number of emitters are arranged on one chip, in other words, on one substrate. There is a method of using this array structure to increase an overall output by approximately a multiple of the number of emitters included in the array structure while maintaining the output per emitter less than or equal to a heat saturation output.

However, even in a semiconductor laser having an array structure (hereinafter referred to as an “array element”), a large amount of heat is still released, and it is therefore important to efficiently radiate the heat. Therefore, for example, in the configuration described in PTL 1, heat radiation efficiency is improved by a package (double-sided metal heat radiation structure) in which both surfaces of an array element are sandwiched between metals. Here, a buffer layer including a bump is provided between the array element and a heat radiation part so as not to apply distortion to the array element.

It is widely known that in the DDL having a light emission wavelength in a 400 nm band, when a light emitting element is caused to emit light for a long period of time without being airtightly sealed, siloxane or the like in the air adheres to an end surface of the light emitting element to deteriorate the light emitting element. Therefore, in a light emitting element using a nitride semiconductor that emits a light in a 400 nm band, it is desirable that a double-sided metal heat radiation structure should be airtightly sealed.

A double-sided metal heat radiation structure applicable to such airtight sealing is disclosed in, for example, PTL 2. In this configuration, the double-sided metal heat radiation structure is airtightly sealed by closing an emission port of a laser beam with a translucent frame.

### CITATION LIST

### Patent Literature

PTL 1: International Publication No. WO 2016/103536

PTL 2: Unexamined Japanese Patent Publication No. 2014-116514

### SUMMARY OF THE INVENTION

In the sealing structure recited in PTL 2, a light emitting element is arranged at a deep position inside a box. However, when a laser beam is emitted from such a deep position, “vignetting” is generated in the laser beam, so that the laser beam cannot be efficiently emitted to the outside. Therefore, in the sealing structure recited in PTL 2, a light guide member protruding inward is provided on an inner surface side of a translucent frame, and a distal end of the light guide member is arranged to be opposed to the light emitting element. As a result, a laser beam incident on the distal end of the light guide member is taken into the light guide member and taken out to the outside via a translucent member.

In general, a laser beam emitted from a light emitting element has a predetermined spread angle. In order to take in, as much as possible, such a spreading light as described above, it is necessary to bring the distal end of the light guide member close to a distance of about several tens of microns from a light emitting surface of the light emitting element. In such fine adjustment work, when the distal end of the light guide member comes into contact with the light emitting surface of the light emitting element during the adjustment, the light emitting surface may be damaged by the contact to deteriorate the light emitting element in some cases.

In view of such a problem, an object of the present disclosure is to provide a semiconductor laser device capable of efficiently emitting a laser beam without damaging a light emitting surface of a light emitting element.

A main aspect of the present disclosure is a semiconductor laser device. The semiconductor laser device according to the present aspect includes a light emitting element, an optical element, a first heat radiation part, and a second heat radiation part. The light emitting element emits a laser beam. The laser beam emitted from the light emitting element is incident on the optical element. The first heat radiation part is connected to the light emitting element. The second heat radiation part is connected to the light emitting element. The first heat radiation part includes a first recess. The second heat radiation part includes a second recess. One end of the optical element is fitted into the first recess. The other end of the optical element is fitted into the second recess.

The semiconductor laser device according to the present aspect enables a laser beam emitted from the light emitting element to be adjusted by the optical element. As a result, the laser beam can be efficiently emitted to the outside. The optical element has a spatial position restricted by the first recess and the second recess. Therefore, even if the optical element is moved during position adjustment of the optical element, the optical element does not accidentally come into contact with a light emitting surface of the light emitting element. It is therefore possible to prevent the optical element from coming into contact with the light emitting surface of the light emitting element and damaging the light emitting surface during the position adjustment of the optical element.

As described in the foregoing, according to the present disclosure, it is possible to provide a semiconductor laser device capable of efficiently emitting a laser beam without damaging a light emitting surface of a light emitting element.

Effects or meanings of the present disclosure will be further clarified in the following description of exemplary embodiments. However, the exemplary embodiments to be described below are merely examples of implementing the present disclosure, and the present disclosure is not at all limited to the following exemplary embodiments.

### BRIEF DESCRIPTION OF THE DRAWINGS

FIG. 1A is a perspective view illustrating a configuration of a semiconductor laser device according to a first exemplary embodiment.

FIG. 1B is a sectional view illustrating the configuration of the semiconductor laser device according to the first exemplary embodiment.

FIG. 2A is a perspective view illustrating an assembly process of the semiconductor laser device according to the first exemplary embodiment.

FIG. 2B is a perspective view illustrating the assembly process of the semiconductor laser device according to the first exemplary embodiment.

FIG. 3A is a perspective view illustrating the assembly process of the semiconductor laser device according to the first exemplary embodiment.

FIG. 3B is a perspective view illustrating the assembly process of the semiconductor laser device according to the first exemplary embodiment.

FIG. 4 is a perspective view illustrating the assembly process of the semiconductor laser device according to the first exemplary embodiment.

FIG. 5A is a sectional view illustrating a configuration of a semiconductor laser device according to a first modified example.

FIG. 5B is a sectional view illustrating a configuration of a semiconductor laser device according to a second modified example.

FIG. 6A is a perspective view illustrating a configuration of a semiconductor laser device according to a second exemplary embodiment of the present invention.

FIG. 6B is a sectional view illustrating the configuration of the semiconductor laser device according to the second exemplary embodiment.

FIG. 7 is a perspective view illustrating an assembly process of the semiconductor laser device according to the second exemplary embodiment.

FIG. 8A is a perspective view illustrating the assembly process of the semiconductor laser device according to the second exemplary embodiment.

FIG. 8B is a perspective view illustrating the assembly process of the semiconductor laser device according to the second exemplary embodiment.

### DESCRIPTION OF EMBODIMENTS

In the following, exemplary embodiments of the present disclosure will be described with reference to the accompanying drawings. For the sake of convenience, an

X-axis, a Y-axis, and a Z-axis perpendicular to each other are added to the drawings. An X-axis positive direction is an emission direction of a laser beam in the semiconductor laser device, and a Y-axis positive direction is a height direction of the semiconductor laser device.

### First Exemplary Embodiment

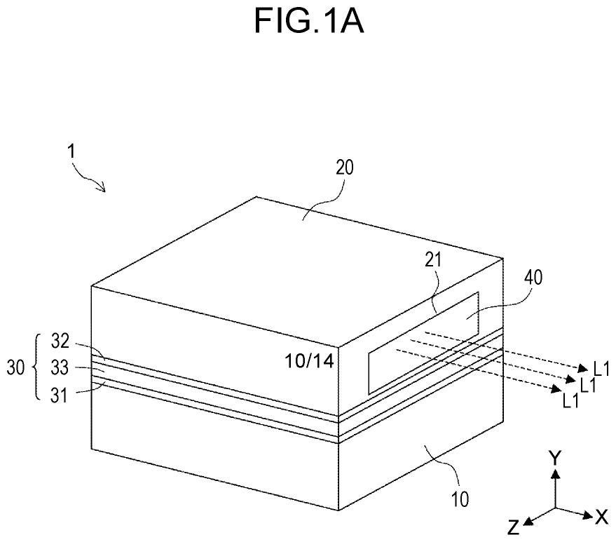

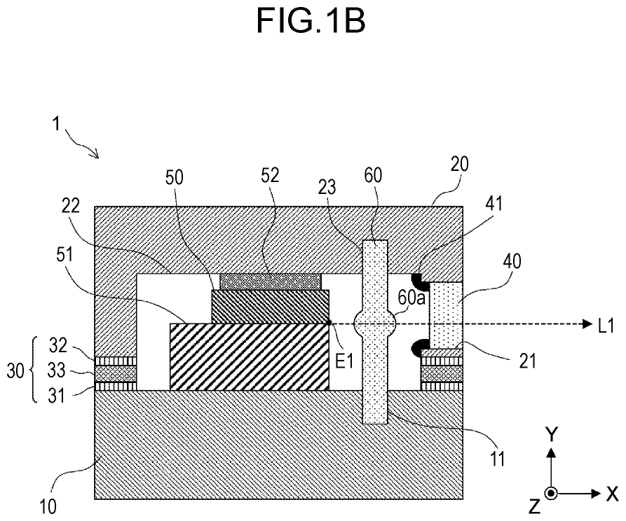

FIG. 1A is an external perspective view illustrating a configuration of semiconductor laser device 1 according to a first exemplary embodiment. FIG. 1B is a sectional view of semiconductor laser device 1 of FIG. 1A taken along a plane parallel to an X-Y plane at a central position in a width direction (a Z-axis direction).

As illustrated in FIGS. 1A and 1B, semiconductor laser device 1 has a rectangular parallelepiped box shape in which first heat radiation part 10 and second heat radiation part 20 are combined. First heat radiation part 10 and second heat radiation part 20 are made of conductive metal having high thermal conductivity. For example, first heat radiation part 10 and second heat radiation part 20 are made of copper. A water-cooling block (not illustrated) is disposed on a lower surface of first heat radiation part 10. Heat generated in semiconductor laser device 1 is propagated to first heat radiation part 10 and radiated to the water-cooling block.

First heat radiation part 10 and second heat radiation part 20 are connected by electrical insulating part 30. Electrical insulating part 30 has a closed annular shape. Electrical insulating part 30 has a shape along outer peripheries of first heat radiation part 10 and second heat radiation part 20. Electrical insulating part 30 includes annular insulating layer 33 having a predetermined thickness, heat-melting layer 31, and heat-melting layer 32. Heat-melting layer 31 is arranged on a lower surface of insulating layer 33, and heat-melting layer 32 is arranged on an upper surface of insulating layer 33. Heat-melting layer 31 and heat-melting layer 32 are made of a material that is melted by heating and solidified by cooling. Insulating layer 33 is made of a non-conductive material. Heat-melting layer 31, heat-melting layer 32, and insulating layer 33 are all made of a material having high thermal conductivity. Heat-melting layer 31 and heat-melting layer 32 are made of, for example, AuSn. Insulating layer 33 is made of, for example, AlN.

Electrical insulating part 30 transfers heat of second heat radiation part 20 to first heat radiation part 10 while maintaining second heat radiation part 20 in an electrically non-contact state with first heat radiation part 10. The heat transferred to first heat radiation part 10 is radiated to the water-cooling block (not illustrated) as described above.

First heat radiation part 10 has a rectangular parallelepiped shape. On the other hand, second heat radiation part 20 has a shape in which recess 22 having a rectangular outline is formed on a lower surface of the rectangular parallelepiped. Rectangular opening 21 communicating with recess 22 is formed on a front surface (a surface on the X-axis positive side) of second heat radiation part 20. Rectangular window member 40 is disposed in opening 21. Window member 40 is made of a material that absorbs less laser beam L1 emitted from light emitting element 50. For example, in a case where laser beam L1 is a laser beam in a blue wavelength band, window member 40 is made of a glass material.

An external size of semiconductor laser device 1 is, for example, 3 cm in width in the Z-axis direction, 3 cm in depth in an X-axis negative direction, and 2 cm in height in the Y-axis positive direction. In the present exemplary embodiment, semiconductor laser device 1 emits three laser beams L1 via window member 40.

As illustrated in FIG. 1B, light emitting element 50 is housed inside semiconductor laser device 1. Light emitting element 50 is a semiconductor laser using a nitride semiconductor (GaN, InGaN, AlGaN, etc.). Light emitting element 50 has three emitters (light emitting parts E1) arranged in the Z-axis direction, and is mounted in a down fashion such that an emitter forming surface faces submount 51.

Light emitting element 50 is connected to first heat radiation part 10 via submount 51. In addition, light emitting element 50 is connected to second heat radiation part 20 via stress relieving layer 52. Submount 51 is made of a conductive material having high thermal conductivity such as CuW. An AuSn layer (not illustrated) is formed at each of an interface between first heat radiation part 10 and submount 51 and an interface between submount 51 and light emitting element 50. Specifically, first heat radiation part 10 and submount 51 are fixed to each other by the AuSn layer and are thermally and electrically connected to each other. In addition, submount 51 and light emitting element 50 are fixed to each other by the AuSn layer and are thermally and electrically connected to each other. Stress relieving layer 52 includes a metal sheet and a gold bump mainly made of gold. Stress relieving layer 52 has a function of conducting electricity and heat and at the same time relieving stress.

Window member 40 is fixed to opening 21 of second heat radiation part 20 by low-melting-point glass 41. Low-melting-point glass 41 is provided from the inside of second heat radiation part 20 over an entire circumference of a joint between window member 40 and opening 21. Thus, a gap of the joint between window member 40 and opening 21 is filled with low-melting-point glass 41. An internal space of semiconductor laser device 1 is made airtight by heat-melting layer 31, heat-melting layer 32, and low-melting-point glass 41. As a result, siloxane or the like does not enter from the outside, so that light emitting element 50 can stably operate over a long period of time.

Furthermore, optical element 60 is housed inside semiconductor laser device 1. Optical element 60 is a rectangular plate-like member as viewed in the X-axis direction. Optical element 60 has three lenses 60a at positions corresponding to the three emitters (light emitting parts El) of light emitting element 50. Each lens 60a is formed in a convex shape on front and back surfaces of optical element 60. Each lens 60a narrows an angle of radiation of laser beam Ll emitted from each light emitting part El of light emitting element 50. For example, each lens 60a collimates laser beam Ll emitted from each light emitting part El of light emitting element 50.

Optical element 60 is disposed inside semiconductor laser device 1 by being sandwiched between first recess 11 formed on an upper surface of first heat radiation part 10 and second recess 23 formed on the lower surface of second heat radiation part 20. Each of first recess 11 and second heat radiation part 20 has a groove shape with constant width and depth.

Here, first recess 11 is formed on the upper surface of first heat radiation part 10 and second recess 23 is formed on the lower surface of second heat radiation part 20 such that gaps between first recess 11 and optical element 60 and between second recess 23 and optical element 60 are substantially eliminated. In this manner, in the disposition state shown in FIG. 1B, optical element 60 hardly moves, and mechanical assembly (so-called passive alignment) becomes possible. In this case, since no adhesive is used inside semiconductor laser device 1, influence of siloxane on light emitting element 50 can be avoided, and extremely high reliability can be ensured.

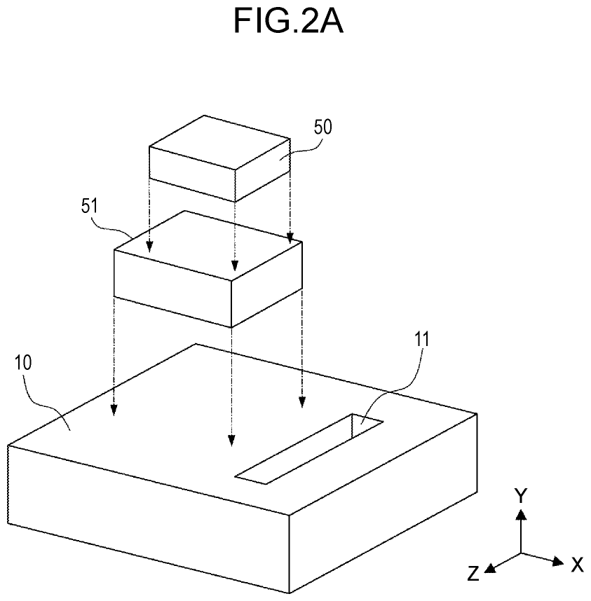

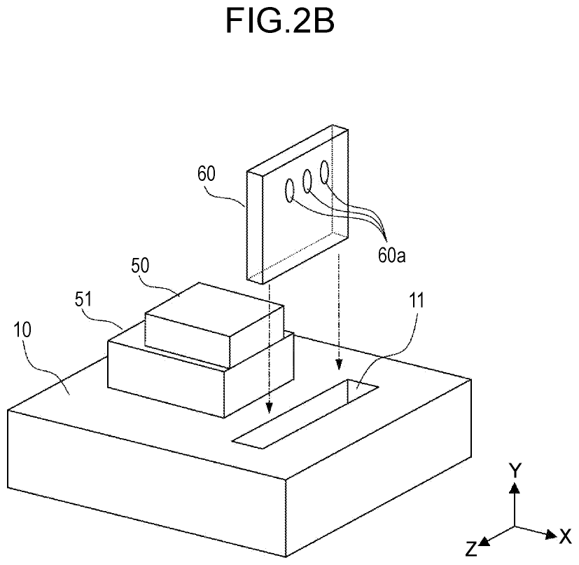

Note that in a case where very highly accurate optical adjustment is required, semiconductor laser device 1 is assembled while the position of optical element 60 is adjusted in a state where laser beam L1 is emitted (so-called active alignment). This assembling method will be described later with reference to FIGS. 2A to 4.

First heat radiation part 10 and second heat radiation part 20 serve also as an electrode of light emitting element 50. Specifically, electric power for light emission is supplied to light emitting element 50 via first heat radiation part 10 and second heat radiation part 20.

Next, assembly processes of semiconductor laser device 1 will be described with reference to FIGS. 2A to 4. FIGS. 2A to 4 are perspective views illustrating the assembly processes of semiconductor laser device 1 according to the first exemplary embodiment. In the AuSn layer used in the following processes, an Sn composition is optimized for each step.

First, as illustrated in FIG. 2A, submount 51 and light emitting element 50 are attached to first heat radiation part 10. In this case, submount 51 and light emitting element 50 may be simultaneously bonded to first heat radiation part 10 with the AuSn layer. Alternatively, regarding submount 51 and light emitting element 50, submount 51 and light emitting element 50 may be bonded to each other with the AuSn layer first, and then submount 51 may be bonded to first heat radiation part 10 with the AuSn layer.

Next, as shown in FIG. 2B, optical element 60 is fitted into first recess 11. As described above, when the passive alignment is performed, almost no gap is required between first recess 11 and optical element 60. On the other hand, when the active alignment is performed, a gap of, for example, about 0.1 mm is preferably provided between first recess 11 and optical element 60.

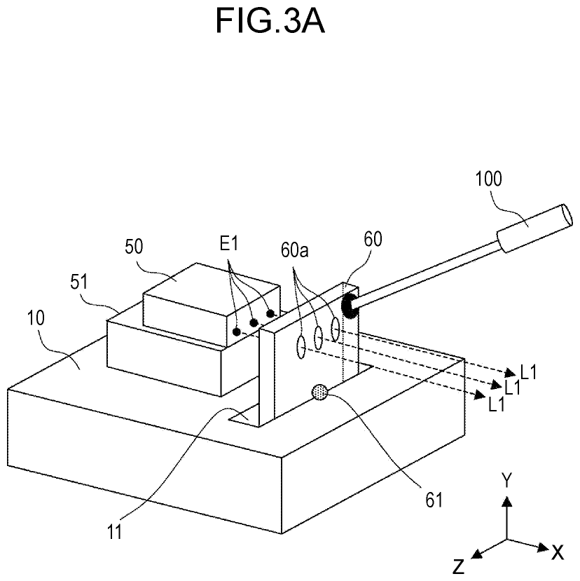

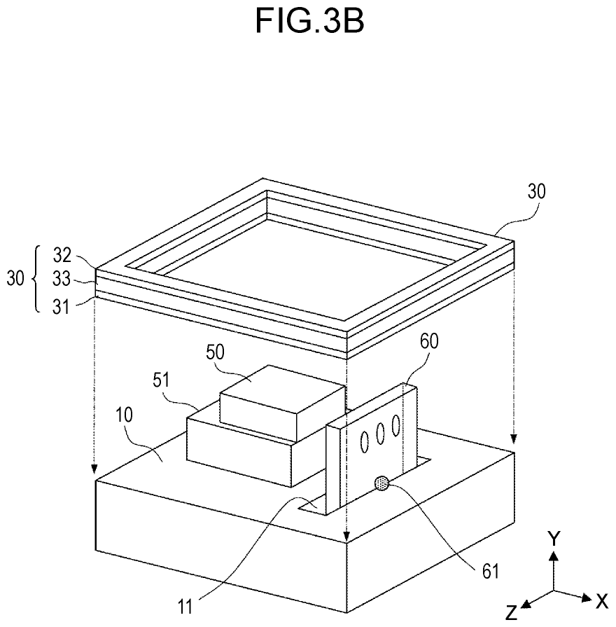

Here, in a case where the active alignment is required for optical element 60, adjustment illustrated in FIG. 3A is performed. In the case of the passive alignment, the adjustment illustrated in FIG. 3A is skipped.

Specifically, as illustrated in FIG. 3A, an operator holds optical element 60 with holding rod (e.g., a vacuum chuck) 100. Next, the operator causes light emitting element 50 to emit laser beam L1, and moves optical element 60 via holding rod 100 so as to optimize distribution, intensity, and the like of laser beam L1 while monitoring an emission state of laser beam L1 with a monitor device. At this time, optical element 60 is in first recess 11. Therefore, even if the operator greatly moves optical element 60, optical element 60 cannot come into contact with an emission surface of light emitting element 50 to damage the emission surface. In other words, first recess 11 serves also as an alignment guide.

Thus, when optical element 60 is positioned at an optimum position, the operator may temporarily fix optical element 60 with a very small amount of ultraviolet curing adhesive 61 in order to temporarily fix optical element 60. In this manner, the active alignment is completed.

Next, as illustrated in FIG. 3B, electrical insulating part 30 is disposed on the upper surface of first heat radiation part 10. As described above, electrical insulating part 30 has heat-melting layer 32 made of AuSn or the like on the upper surface of annular insulating layer 33 made of AlN (ceramic) or the like. On the lower surface of insulating layer 33, heat-melting layer 31 made of AuSn or the like is provided. At this time, first heat radiation part 10 may be slightly heated to slightly melt heat-melting layer 31, thereby temporarily fixing electrical insulating part 30 to the upper surface of first heat radiation part 10.

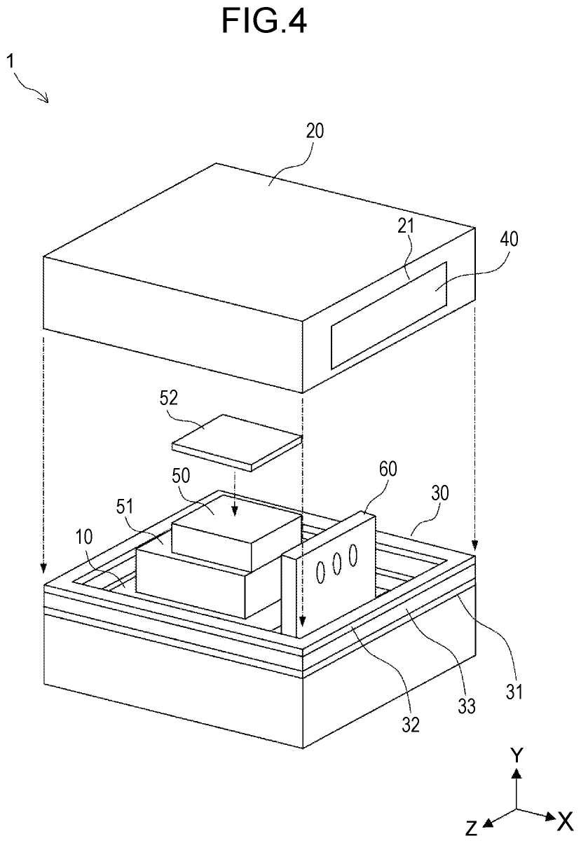

Next, as illustrated in FIG. 4, stress relieving layer 52 including a gold bump and a metal foil is formed on an upper surface of light emitting element 50. In addition, second heat radiation part 20 in which window member 40 is attached to opening 21 is disposed on an upper surface of electrical insulating part 30. At this time, optical element 60 is fitted into second recess 23 (see FIG. 1B) formed on the lower surface of second heat radiation part 20. Then, a pressure is applied to first heat radiation part 10 and second heat radiation part 20 in a direction approaching to each other such that optical element 60 receives a pressure in a Y axis direction from first recess 11 and second recess 23.

In this state, heat-melting layer 31 and heat-melting layer 32 of electrical insulating part 30 are heated and melted to be brought into close contact with first heat radiation part 10 and second heat radiation part 20. Thereafter, heat-melting layer 31 and heat-melting layer 32 are cooled and solidified. As a result, first heat radiation part 10 and second heat radiation part 20 are combined via electrical insulating part 30, and the inside of semiconductor laser device 1 is airtightly sealed up. At this time, optical element 60 is sandwiched upon receiving the pressure in the Y-axis direction from first recess 11 and second recess 23, and is fixed inside semiconductor laser device 1. Thus, the assembly of semiconductor laser device 1 is completed.

### Effects of Semiconductor Laser Device 1 According to First Exemplary Embodiment

Semiconductor laser device 1 according to the first exemplary embodiment has the following effects.

Laser beam L1 emitted from light emitting element 50 is adjusted by optical element 60. As a result, laser beam L1 can be efficiently emitted to the outside. In addition, a spatial position of optical element 60 is restricted by first recess 11 and second recess 23. Therefore, for example, even if optical element 60 is moved during position adjustment of optical element 60, optical element 60 does not accidentally come into contact with a light emitting surface of light emitting element 50. It is therefore possible to prevent optical element 60 from coming into contact with the light emitting surface of light emitting element 50 and damaging the light emitting surface during the position adjustment of optical element 60.

As illustrated in FIG. 1B, second heat radiation part 20 is combined with first heat radiation part 10 to form a housing space for light emitting element 50 and optical element 60. Thus, light emitting element 50 and optical element 60 can be airtightly housed in semiconductor laser device 1.

As illustrated in FIG. 3A, optical element 60 is a plate-formed member having lens 60a for narrowing the angle of radiation of laser beam L1. As a result, both ends of optical element 60 can be smoothly held by first recess 11 and second recess 23, and the spatial position of optical element 60 can be smoothly restricted by first recess 11 and second recess 23.

As illustrated in FIG. 1B, optical element 60 is sandwiched and fixed between first recess 11 and second recess 23 by combining first heat radiation part 10 and second heat radiation part 20. As a result, since optical element 60 can be fixed without using an adhesive or the like, generation of siloxane can be suppressed, thereby suppressing deterioration of light emitting element 50 due to siloxane. Therefore, reliability of semiconductor laser device 1 can be enhanced.

As illustrated in FIG. 3A, light emitting element 50 includes a plurality of light emitting parts E1. Optical element 60 includes a plurality of lenses 60a on which laser beams L1 emitted from the plurality of light emitting parts E1 is incident. By providing the plurality of light emitting parts E1 in this manner, the output of semiconductor laser device 1 can be increased. Furthermore, by integrally providing the plurality of lenses 60a in optical element 60, the plurality of lenses 60a can be associated with the plurality of light emitting parts E1 according to the disposition of optical element 60. Therefore, lenses 60a can be appropriately and easily arranged.

As shown in FIG. 1B, each of first heat radiation part 10 and second heat radiation part 20 is made of a conductive metal material. First heat radiation part 10 is electrically connected to light emitting element 50 by submount 51 (a fixing part). Second heat radiation part 20 is electrically connected to light emitting element 50 by stress relieving layer 52 (a second fixing part). First heat radiation part 10 and second heat radiation part 20 are combined with each other via electrical insulating part 30. As a result, first heat radiation part 10 and second heat radiation part 20 can be used as electrodes for supplying electric power to light emitting element 50. Therefore, it is not necessary to additionally provide wiring for electric power supply inside semiconductor laser device 1, and is possible to simplify the configuration of semiconductor laser device 1.

As shown in FIGS. 1A and 1B, electrical insulating part 30 has heat-melting layer 31 on the upper surface of insulating layer 33 and heat-melting layer 32 on the lower surface of insulating layer 33. When heat-melting layer 31 and heat-melting layer 32 are melted by heating, first heat radiation part 10 and second heat radiation part 20 are combined with each other via electrical insulating part 30. As a result, first heat radiation part 10 and second heat radiation part 20 can be easily assembled while securing electrical insulation between first heat radiation part 10 and second heat radiation part 20.

### FIRST MODIFIED EXAMPLE

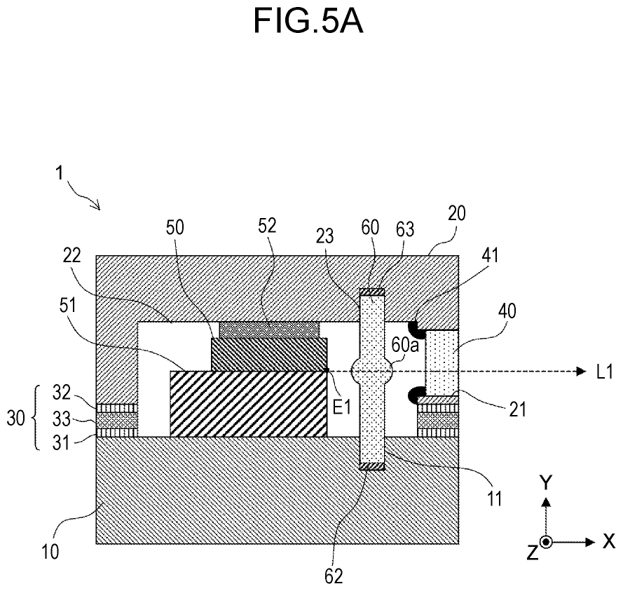

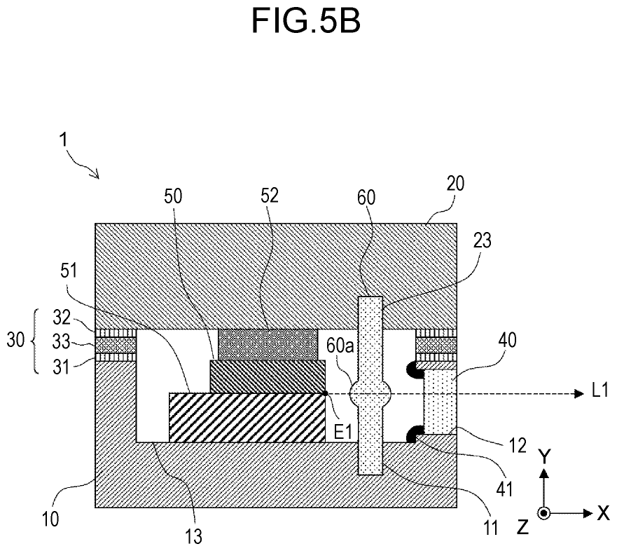

FIG. 5A is a sectional view of semiconductor laser device 1 according to a first modified example.

In the first modified example, buffer material 62 is provided between optical element 60 and first recess 11, and buffer material 63 is provided between optical element 60 and second recess 23. Buffer material 62 and buffer material 63 are desirably, for example, rubber or aluminum foils not containing siloxane.

In a case where buffer material 62 and buffer material 63 are provided in this manner, an extremely strong pressure is not applied to optical element 60 when first heat radiation part 10 and second heat radiation part 20 are combined. This makes it possible to prevent optical element 60 from being damaged by the pressure from first recess 11 and second recess 23.

Although in the configuration of FIG. 5A, two buffer materials 62 and 63 are provided, buffer material 62 or buffer material 63 may be provided only between optical element 60 and first recess 11 or between optical element 60 and second recess 23.

### SECOND MODIFIED EXAMPLE

FIG. 5B is a sectional view of semiconductor laser device 1 according to a second modified example.

In the second modified example, recess 13 and opening 12 (an opening corresponding to opening 21 of the first exemplary embodiment) are provided in first heat radiation part 10, and second heat radiation part 20 has a rectangular parallelepiped shape. The other parts of the configuration are the same as those of the first exemplary embodiment. The present modification may achieve the same effects as those of the first exemplary embodiment described above.

Also in the configuration of FIG. 5B, similarly to FIG. 5A, a buffer material may be provided at least one of between optical element 60 and first recess 11 and between optical element 60 and second recess 23.

### Second Exemplary Embodiment

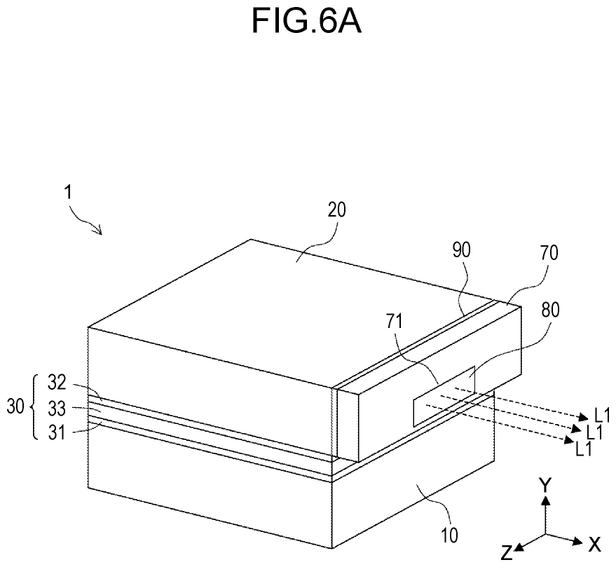

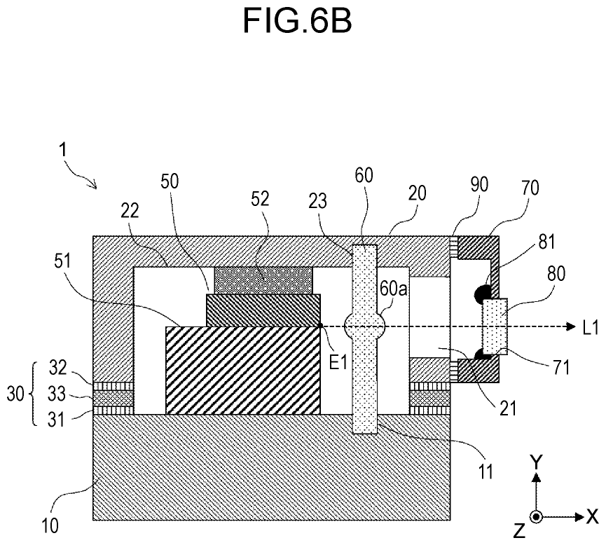

FIG. 6A is an external perspective view illustrating a configuration of semiconductor laser device 1 according to a second exemplary embodiment. FIG. 6B is a sectional view of semiconductor laser device 1 of FIG. 6A taken along a plane parallel to the X-Y plane at the center position in the Z-axis direction.

In the second exemplary embodiment, as compared with the first exemplary embodiment, cover 70 is added, and window member 80 is disposed in cover 70. No window member is disposed in opening 21 formed in second heat radiation part 20, the opening being a space through which laser beam L1 can pass. Window member 80 is fitted into rectangular opening 71 formed in cover 70, and is fixed to cover 70 from the inside by low-melting-point glass 81. Low-melting-point glass 81 is provided at a joint between opening 71 and window member 80 over an entire periphery of the joint. Cover 70 is made of, for example, copper.

Cover 70 is attached to a front surface of second heat radiation part 20 via heat-melting layer 90 made of AnSn or the like. After being collimated by optical element 60, laser beam L1 emitted from light emitting element 50 passes through opening 21 and window member 80, and is then output to the outside.

In the first exemplary embodiment, when the active alignment shown in FIG. 3A is performed, the operator needs to perform work for the active alignment before attaching second heat radiation part 20 to first heat radiation part 10. For this reason, the operator needs to temporarily fix optical element 60 with ultraviolet curing adhesive 61 or the like before attaching second heat radiation part 20 to first heat radiation part 10, and the number of processes for assembly is accordingly increased. In contrast, in the second exemplary embodiment, since when second heat radiation part 20 is combined with first heat radiation part 10, optical element 60 can be aligned, it is not necessary to temporarily fix optical element 60.

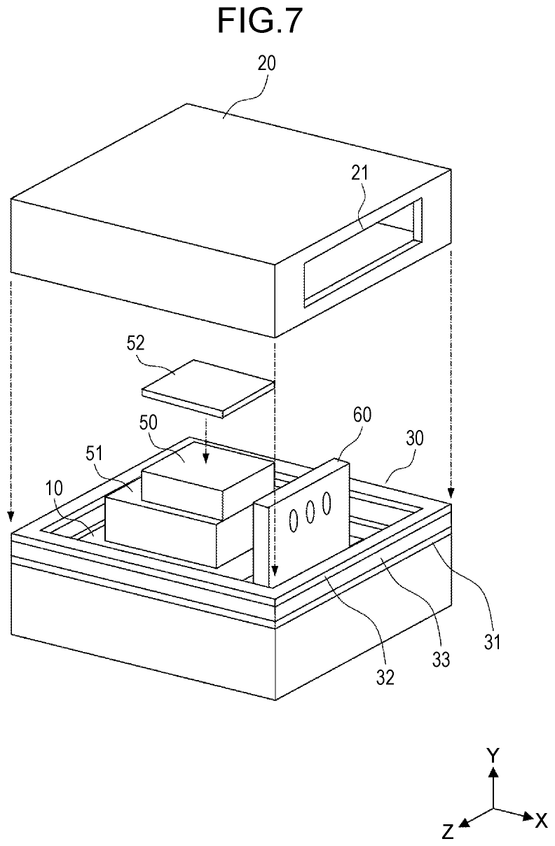

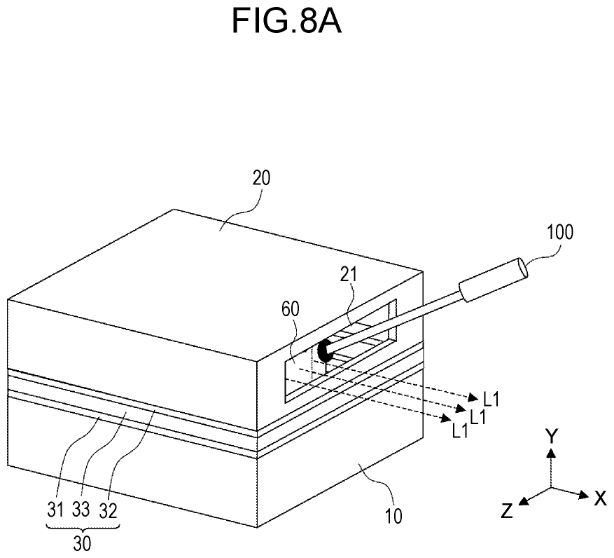

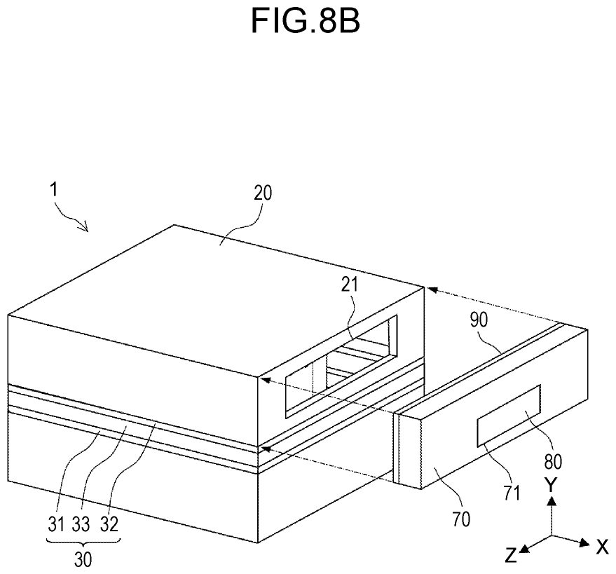

Assembly processes of semiconductor laser device 1 according to the second exemplary embodiment will be described with reference to FIGS. 7 to 8B. FIGS. 7 to 8B are perspective views illustrating the assembly processes of semiconductor laser device 1 according to the second exemplary embodiment. Also in the following processes, as in the first exemplary embodiment described above, an Sn composition of the AuSn layer is optimized for each process.

Processes up to disposition of electrical insulating part 30 on the upper surface of first heat radiation part 10 are similar to those in the first exemplary embodiment. After electrical insulating part 30 is disposed on the upper surface of first heat radiation part 10, as illustrated in FIG. 7, stress relieving layer 52 including a gold bump and a metal foil is formed on the upper surface of light emitting element 50. Further, second heat radiation part 20 having opening 21 is attached to the upper surface of electrical insulating part 30 with a light pressure. In the second exemplary embodiment, no window member is disposed in opening 21.

In the case of performing the active alignment, as illustrated in FIG. 8A, the operator causes light emitting element 50 to emit laser beam L1 before fixing second heat radiation part 20 to electrical insulating part 30. At this time, second heat radiation part 20 is electrically connected to light emitting element 50 via stress relieving layer 52 to such an extent that electric power is conducted by the light pressure applied to the upper surface.

The operator holds optical element 60 with holding rod (e.g., a vacuum chuck) 100 through opening 21. Next, the operator moves optical element 60 via holding rod 100 so as to optimize the distribution, the intensity, and the like of laser beam L1 while monitoring the emission state of laser beam L1 with the monitor device. At this time, since optical element 60 is in first recess 11 and second recess 23 (see FIG. 6B), even if the operator greatly moves optical element 60, optical element 60 cannot come into contact with the emission surface of light emitting element 50 and damage the emission surface. In other words, first recess 11 and second recess 23 serve also as alignment guides.

In this manner, when the alignment of optical element 60 is completed, while applying heat to electrical insulating part 30, the operator brings first heat radiation part 10 and second heat radiation part 20 into close contact with electrical insulating part 30 under pressure to attach second heat radiation part 20 to first heat radiation part 10. As a result, optical element 60 is sandwiched between first recess 11 and second recess 23 and fixed inside first heat radiation part 10 and second heat radiation part 20.

Thereafter, as illustrated in FIG. 8B, the operator attaches, to the front surface of second heat radiation part 20, cover 70 to which heat-melting layer 90 and window member 80 are attached in advance. Heat-melting layer 90 is provided along an outer edge of a surface of cover 70 on the X-axis negative side over an entire periphery of the outer edge. While applying heat to heat-melting layer 90, the operator brings cover 70 into close contact with the front surface of second heat radiation part 20 under pressure and then cools and solidifies heat-melting layer 90. As a result, cover 70 is fixed to second heat radiation part 20 to complete the assembly of semiconductor laser device 1.

Since opening 21 is closed by cover 70, the inside of semiconductor laser device 1 is airtightly sealed. Therefore, intrusion of siloxane from the outside is suppressed.

Also in the second exemplary embodiment, the configurations of the first modified example shown in FIG. 5A and the second modified example shown in FIG. 5B may be applied.

### Effects of Semiconductor Laser Device 1 According to Second Exemplary Embodiment

In semiconductor laser device 1 according to the second exemplary embodiment, the same effects as those of the first exemplary embodiment can be obtained.

According to the second exemplary embodiment, as shown in FIG. 8A, first heat radiation part 10 and second heat radiation part 20 are combined to form a box, the box including opening 21 for allowing laser beam L1 having transmitted through optical element 60 to pass therethrough. Furthermore, as illustrated in FIG. 8B, semiconductor laser device 1 includes cover 70 that closes opening 21, cover 70 having window member 80 that transmits laser beam L1 having passed through opening 21. As a result, when performing the active alignment on optical element 60, the operator can adjust the position of optical element 60 in a state where optical element 60 is sandwiched between first recess 11 of first heat radiation part 10 and second recess 23 of second heat radiation part 20 as illustrated in FIG. 8A. Thereafter, optical element 60 can be fixed by fixing second heat radiation part 20 to first heat radiation part 10. Therefore, it is possible to reliably fix optical element 60 whose position has been adjusted at the position, and accordingly improve beam quality of laser beam L1.

### OTHER MODIFIED EXAMPLES

Although the exemplary embodiments of the present disclosure have been described in the foregoing, the present disclosure is not limited to the above exemplary embodiments, and various other modifications can be made.

For example, although in the first exemplary embodiment and the second exemplary embodiment, three light emitting parts E1 are provided in light emitting element 50, the number of light emitting parts E1 is not limited thereto. In addition, light emitting parts E1 may not necessarily be arranged in the Z-axis direction, and may be arranged in a matrix, for example. The arrangement of lenses 60a only needs to be changed according to the arrangement of light emitting parts E1.

In the first exemplary embodiment and the second exemplary embodiment, opening 21 through which laser beam L1 passes is formed in second heat radiation part 20, and in the second modified example, opening 12 through which laser beam L1 passes is formed in first heat radiation part 10. However, the form of the opening is not limited to this, and the opening may be formed in the box formed by combining first heat radiation part 10 and second heat radiation part 20. For example, a notch may be formed in each of first heat radiation part 10 and second heat radiation part 20, and first heat radiation part 10 and second heat radiation part 20 may be combined to combine the notches, thereby forming an opening.

In the first exemplary embodiment and the second exemplary embodiment, first recess 11 and second recess 23 each have a groove shape with constant width and depth. However, as long as the movement of optical element 60 can be restricted so as not to come in contact with the light emitting surface of light emitting element 50, first recess 11 and second recess 23 may have other shapes. For example, an inclined surface that increases a width of second recess 23 toward the lower surface of second heat radiation part 20 may be formed at an inlet of second recess 23. This enables optical element 60 to be smoothly fitted into second recess 23 at the time of combining second heat radiation part 20 with first heat radiation part 10. A similar inclined surface may be formed also in first recess 11.

Although in the first exemplary embodiment and the second exemplary embodiment, electric power is supplied to light emitting element 50 via stress relieving layer 52, second heat radiation part 20 and the upper surface of light emitting element 50 may be connected by wiring to supply electric power to light emitting element 50. It is noted that in this case, since it is necessary to separately provide wiring, the configuration becomes complicated, and assembly work becomes troublesome. In contrast, according to the configurations of the first exemplary embodiment and the second exemplary embodiment, since electric power is supplied to light emitting element 50 via stress relieving layer 52, it is possible to simplify the configuration and facilitate the assembly work.

Note that semiconductor laser device 1 may be used not exclusively for processing of a product, and may be used for other purposes. A wavelength band of laser beam L1 may be a wavelength band other than the blue wavelength band. A shape and a size of opening 21, and a material, composition, and a shape of each member constituting semiconductor laser device 1 can also be changed as appropriate.

In addition, various modifications can be appropriately made to the exemplary embodiments of the present disclosure within the scope of the technical idea disclosed in the claims.

In the configurations of the first exemplary embodiment and the second exemplary embodiment, in a case where a nitride semiconductor array having 40 light emitting parts E1 is used as light emitting element 50, and the lower surface of first heat radiation part 10 is cooled with water, 20,000 hours or more of life of the device can be secured for 100 watt operation.

### INDUSTRIAL APPLICABILITY

According to the semiconductor laser device of the present disclosure, the internal space of the semiconductor laser device is made airtight without damaging the light emitting surface of the light emitting element. This prevents siloxane or the like from entering from the outside, and enables the light emitting element to efficiently emit a laser beam and stably operate for a long period of time. Therefore, the semiconductor laser device according to the present disclosure can be used for, for example, high quality processing. In other words, the semiconductor laser device of the present disclosure is industrially useful.

### REFERENCE MARKS IN THE DRAWINGS

1: semiconductor laser device

10: first heat radiation part

11: first recess

12, 21, 71: opening

20: second heat radiation part

23: second recess

30: electrical insulating part

31, 32, 90: heat-melting layer

33: insulating layer

40, 80: window member

50: light emitting element

51: submount (first fixing part)

52: stress relieving layer (second fixing part)

60: optical element

60a: lens

62, 63: buffer material

70: cover

E1: light emitting part

1. A semiconductor laser device comprising:
a light emitting element that emits a laser beam;
an optical element on which the laser beam emitted from the light emitting element is incident;
a first heat radiation part connected to the light emitting element; and
a second heat radiation part connected to the light emitting element,
wherein
the first heat radiation part includes a first recess, and the second heat radiation part includes a second recess, and
one end of the optical element is fitted into the first recess, and another end of the optical element is fitted into the second recess.

2. The semiconductor laser device according to claim 1, wherein the second heat radiation part is combined with the first heat radiation part to form a housing space for the light emitting element and the optical element.

3. The semiconductor laser device according to claim 1, wherein the optical element is a plate-formed member having a lens for narrowing an angle of radiation of the laser beam.

4. The semiconductor laser device according to claim 1, wherein the optical element is sandwiched and fixed between the first recess and the second recess by combining the first heat radiation part and the second heat radiation part.

5. The semiconductor laser device according to claim 1, wherein a buffer material is interposed at least one of between the optical element and the first recess and between the optical element and the second recess.

6. The semiconductor laser device according to claim 1, wherein
the first heat radiation part and the second heat radiation part are combined to form a box,
the box includes an opening for allowing the laser beam having transmitted through the optical element to pass therethrough, and further includes a cover that closes the opening, and
the cover includes a window member that transmits the laser beam having passed through the opening.

7. The semiconductor laser device according to claim 1, wherein
the light emitting element includes a plurality of light emitting parts, and
the optical element includes a plurality of the lenses on which laser beams emitted from the plurality of light emitting parts are incident.

8. The semiconductor laser device according to claim 1, wherein
the first heat radiation part and the second heat radiation part are made of a conductive metal material, and are electrically connected to the light emitting element by a first fixing part and a second fixing part, respectively, and
the first heat radiation part and the second heat radiation part are combined with each other via an electrical insulating part.

9. The semiconductor laser device according to claim 8, wherein
the electrical insulating part includes an insulating layer and heat-melting layers on upper and lower surfaces of the insulating layer, and
the first heat radiation part and the second heat radiation part are combined with each other via the electrical insulating part by melting of the heat-melting layers by heating.
